(19) United States
(12) Patent Application Publication
(10) Pub. No.: US 2024/0322186 A1
(43) Pub. Date: Sep. 26, 2024

(54) ELECTRODE PROTECTIVE LAYER, AND PREPARATION METHOD THEREFOR AND USE THEREOF

(71) Applicant: SHENZHEN YUANSU OPTOELECTRONICS TECHNOLOGY CO., LTD., SHENZHEN, Guangdong (CN)

(72) Inventors: Weizhen WANG, SHENZHEN, Guangdong (CN); Yanlong BAI, SHENZHEN, Guangdong (CN); Zhefeng LI, SHENZHEN, Guangdong (CN); Ann Lincu XIN, SHENZHEN, Guangdong (CN); Lu SHEN, SHENZHEN, Guangdong (CN); Luoyuan XIE, SHENZHEN, Guangdong (CN)

(21) Appl. No.: 18/580,146

(22) PCT Filed: Aug. 19, 2022
(86) PCT No.: PCT/CN2022/113714

§ 371 Date: Jan. 17, 2024

(30) Foreign Application Priority Data
Aug. 27, 2021 (CN) 202110994226.8

(51) Int. Cl. H01M 4/62; C23C 14/08; C23C 14/35; C23C 16/02; C23C 16/40; C23C 16/455; H01M 4/02; H01M 4/04; H01M 4/133; H01M 4/36; H01M 4/587

(52) U.S. Cl. CPC H01M 4/628; C23C 14/08; C23C 14/35; C23C 16/0227; C23C 16/40; C23C 16/405; C23C 16/406; C23C 16/407; C23C 16/408; C23C 16/45529; C23C 16/45531; C23C 16/45555; H01M 4/0426; H01M 4/0428; H01M 4/133; H01M 4/366; H01M 4/587; H01M 2004/021; H01M 2004/027

(57) ABSTRACT

The present disclosure relates to an electrode protective layer, and a preparation method therefor and the use thereof. The electrode protective layer comprises a metal oxide and has a one-layer laminated structure, and the metal oxide is ionically conductive; and the surface of a negative electrode plate of a secondary battery is coated with the electrode protective layer. The electrode protective layer has the effects of improving the safety performance and cycle performance of a secondary battery; the preparation method is simple and has high applicability; and the electrode protective layer can be used in various batteries and various fields.

### TECHNICAL FIELD

The present disclosure belongs to the technical field of secondary battery materials, and specifically relates to an electrode protective layer, and preparation method and use thereof.

### BACKGROUND

During the first charge and discharge process of conventional liquid secondary battery (including lithium-ion battery), the electrode material reacts with the electrolyte on the solid-liquid interface, forming an electrode protective layer covering the surface of negative electrode. Such electrode protective layers have the characteristics of solid electrolyte, which can block the electrolyte molecules passing through and allow the active metal ions (lithium ions in lithium-ion batteries) to shuttle in it, thus protecting the negative electrode active material to a certain extent, and it is called solid electrolyte interface film (SEI film).

However, the naturally generated SEI film is unstable during charge and discharge cycles of the secondary battery. Particularly under high temperature conditions, the SEI film is prone to rupture or delamination, leading to the erosion of the active material in negative electrode by the electrolyte. It not only weakens the capacity of the secondary battery but also easily poses safety hazards.

In order to solve the related technical problems, researchers propose to prepare a passivation protective layer on the surface of the negative plate so as to protect active materials in negative electrode. For example, using atomic layer deposition (ALD) to from a passivation protective film. Such protective film has a compact structure, and can cover the negative surface with complex surface structure without gaps. At the same time, it maintains stable chemical properties during the charge and discharge processes of secondary battery, which is beneficial to prolonging the cycle life of the secondary battery such as lithium-ion secondary battery greatly.

The ALD passivation film materials used by related technology are mostly conventional aluminum oxide and hafnium oxide (Al₂O₃ and HfO₂) etc, and the ALD preparation process for such material is mature and has quite excellent chemical stability.

However, the protective layer provided by the conventional technology can not provide a good protective effect if the thickness is too thin, or will affect the working performance of the secondary battery if the thickness is too thick.

### SUMMARY

The present disclosure aims to solve at least one of the technical problems in the prior art.

Therefore, the first aspect of the present disclosure provides an electrode protective layer, which is made of a specific material and has a specific structure, so that it can have a protective effect on the negative electrode plate of secondary battery without affecting its working performance.

The second aspect of the present disclosure provides a preparation method for the electrode protective layer.

The third aspect of the present disclosure further provides a negative electrode with the aforementioned electrode protective layer.

The fourth aspect of the present disclosure further provides a secondary battery with the aforementioned negative electrode.

The fifth aspect of the present disclosure further provides use of the secondary battery in the fields of 3C, energy storage and power batteries.

According to the first aspect of the present disclosure, provids an electrode protective layer comprising a metal oxide and having a 1 to multi-layer laminated structure, and the metal oxide has ionic conductivity.

The electrode protective layer according to an embodiment of the present disclosure at least has the following beneficial effects:

(1) The electrode protective layer according to the present disclosure is attached to the surface of negative electrode plate and has physical protection effect on the negative electrode plate; that is, the direct contact between the negative electrode plate and the electrolyte is physically isolated, so that the corrosion of negative electrode active material by the electrolyte can be avoided. If the secondary battery comprises the electrode protective layer provided by the present disclosure, the safety performance and the cycle stability of the secondary battery can be effectively improved.

(2) The electrode protective layer according to the present disclosure has ionic conductivity. The ionic conductivity can ensure that active ions (including lithium ions, sodium ions, potassium ions, aluminum ions and the like) of the secondary battery enter and desorb from the electrode protective layer through mechanisms such as lattice intercalation-deintercalation, oxidation-reduction reaction and alloying reaction. That is to say, the aforementioned electrode protective layer not only has the physical protection effect, but also has the characteristics of solid electrolyte, so that coating the electrode protective layer on the surface of the negative electrode plate of the secondary battery does not affect the ion transmission performance of the battery, and also greatly improves the battery performance, such as the cycle performance of the lithium-ion battery. And its requirement for thickness precision is low, which can form a thicker coating and provide reliable passivation protection effect for the negative electrode.

According to some embodiments of the present disclosure, the electrode protective layer is set on the surface of the negative electrode plate of the secondary battery.

According to some embodiments of the present disclosure, the electrode protective layer has a thickness of ≥0.1 nm.

According to some embodiments of the present disclosure, the electrode protective layer has the thickness of 0.1-20 nm.

According to some preferred embodiments of the present disclosure, the electrode protective layer has the thickness of 1-10 nm.

The electrode protective layer provided by the present disclosure can have a laminated structure. Within the thickness range of the electrode protection layer mentioned above, it is known that each laminated layer is very thin, can especially alleviate the structural instability caused by character mismatch among different laminated layers, and further provide guarantees for the laminated structure of various components.

According to some embodiments of the present disclosure, the ionic conductivity is at least one of lithium ion conductivity, sodium ion conductivity, and potassium ion conductivity.

According to some embodiments of the present disclosure, the metal oxide comprises at least one of binary oxide and ternary oxide.

According to some embodiments of the present disclosure, the binary oxide has a general formula of AOₘ.

In the AOₘ, A is selected from at least one of the group consisting of V, Mo, Nb, Sb, Ge, Sn, Cd, In, Co, Ti, Fe, Mn, Ni, W, Cu, Mg, Si and Cr, and 1≤m≤3.

According to some embodiments of the present disclosure, the AOₘ is at least one of stoichiometric oxide and non-stoichiometric oxide.

The stoichiometric oxide refers to an oxide having a defined composition and having a simple integer ratio of atoms of various elements to each other, such as carbon monoxide, wherein the atomic ratio of oxygen to carbon is constantly 1:1.

The non-stoichiometric oxide refers to an oxide where the number of atoms of various elements is uncertain and can not form a definite simple integer ratio, or where atoms except oxygen atoms do not comply with the valence rule, such as Co_{(0.9-1.1)}O_{1.3}.

According to some embodiments of the present disclosure, the stoichiometric oxide of AOₘ is selected from at least one of the group consisting of VO, VO₂, V₂O₅, VₙO₂ₙ₋₁, MoO₃, Nb₂O₅, Sb₂O₃, GeO₂, ZnO, CdO, In₂O₃, CoO, Co₃O₄, FeO, Fe₂O₃, Fe₃O₄, MnO, Mn₂O₃, Mn₃O₄, NiO, CuO, and Cr₂O₃.
in the VₙO₂ₙ₋₁, n is a positive integer.

According to some preferred embodiments of the present disclosure, the AOₘ is at least one of CoO, NiO, and CuO.

According to some preferred embodiments of the present disclosure, the AOₘ is at least one of CoO.

According to some embodiments of the present disclosure, the ternary oxide is at least one of titanate, niobate, stannate, antimonate and other transition-metal ternary oxides satisfying the general formula of XY₂O₄.

According to some embodiments of the present disclosure, the X and Y in the XY₂O₄ are independently selected from one of the group consisting of Mn, Fe, Co, Ni and Cu, and the condition is that the X and the Y are different.

According to some embodiments of the present disclosure, the titanate is selected from at least one of the group consisting of Li₄Ti₅O₁₂ and MgTi₂O₅.

According to some embodiments of the present disclosure, the niobate is TiNb₂O₇.

According to some embodiments of the present disclosure, the stannate is selected from at least one of the group consisting of Mg₂SnO₄, MgSnO₃, Mn₂SnO₄, Co₂SnO₄, CoSnO₃, Zn₂SnO₄, CaSnO₃, SrSnO₃, and Li₂SnO₃.

According to some embodiments of the present disclosure, the antimonate is selected from at least one of the group consisting of CoSb₂O₆, NiSb₂O₆, and CuSb₂O₆.

According to some embodiments of the present disclosure, the electrode protective layer is a single-layer structure or a laminated structure.

According to some embodiments of the present disclosure, the laminated structure is a laminated structure formed by overlapping arrangements of multiple components; for example, it can comprises sequentially formed 1 nm CoO layers and 1 nm NiO layers.

Specifically, the laminated structure may be a 5× (1 nm CoO/1 nm NiO) nano-laminated structure, which indicates that the single layer of CoO or NiO has a thickness of about 1 nm, and the two materials are alternated 5 times to form the laminated structure. And the laminated structure may also be 10× (0.5 nm CoO/0.5 nm NiO), 5× (1 nm CuO/1 nm NiO), 8× (0.5 nm FcO/1 nm MnO) and the like.

The laminated structure formed by multiple components contributes to reduce stress concentration of the thin film caused by lattice or thermal expansion mismatch.

According to the second aspect of the present disclosure, there is provided a preparation method for the electrode protective layer, wherein the preparation method is an atomic layer deposition method, a chemical vapor deposition method, a physical vapor deposition method, or a combination thereof.

The preparation method for the electrode protective layer according to an embodiment of the present disclosure at least has the following beneficial effects.

The atomic layer deposition method, the chemical vapor deposition method and the physical vapor deposition method can achieve uniform deposition of films made of specific materials, and can accurately control the thicknes. Meanwhile, it can prepare multi-component, double-layer, multi-layer or other nano-laminated structures by replacing the raw materials for preparation.

In some embodiments, the atomic layer deposition method is one of thermal atomic layer deposition method or plasma-enhanced atomic layer deposition method, or a combination thereof.

Although the method of coating negative active material to improve the battery performance is common, due to directly set the electrode protective layer on the surface of the electrode plate requires that generating a uniform, compact and continuous extremely thin film the surface of the electrode plate without causing substantial damage to carbon-based materials such as adhesives and conductive agents on the surface of the electrode plate, which requires higher technical requirements. Therefore, the common coating technology is more suitable for being applied to powdery negative active materials and is not suitable for being directly applied to negative electrode plates. The present disclosure uses the atomic layer deposition (ALD) method to solve the problems of low yield, high cost, complex process and the like of directly setting the electrode protective layer on the negative electrode plate by adjusting parameters.

Since ALD method is generally performed at a lower temperature, and limited by the thermal activation energy, only a small number of atoms in the electrode protective layer can diffuse to the ideal lattice sites, resulting in the electrode protective layer obtained by ALD method generally having an amorphous structure. The amorphous structure generally has superior corrosion resistance compared to crystalline material of the same composition, and the mechanism is that the amorphous material does not have crystal defects such as grain boundaries or dislocations, which are easily eroded by external liquid or gas. Therefore, the electrode protective layer prepared by the present disclosure has good passivation protection effect (physical isolation performance) due to the formation of compact amorphous structure.

The principle of atomic layer deposition is as follows: the single atomic layers are alternately chemically adsorbed on the surface of the sample through saturation, the adjacent adsorbed atomic layers react. When the adjacent adsorbed layers contain metal atoms and oxygen atoms, a dense metal oxide film is formed, so that the atomic layer deposition film has a compact structure, and there are almost no micropores and microcracks in the film layer. That is, the electrode protective layer has a compact structure, so that the double electrode protective layer prepared by atomic layer deposition has a good passivation protection effect.

According to some embodiments of the present disclosure, the atomic layer deposition method comprises the following steps:
E1. placing the negative electrode plate of the secondary battery in the chamber of an atomic layer deposition system, vacuumizing, and sequentially or simultaneously introducing an isolation gas, a metal precursor and an oxygen-containing reactant into the atomic layer deposition chamber;
E2. starting the moving mechanism to enable the plate to move and pass through the deposition area of the chamber for 1 to multiple times, so as to obtain the electrode protective layer.

The atomic layer deposition method shown in steps E1 to E2 is a dynamic atomic layer deposition method, which is also called as a roll-to-roll atomic layer deposition method. Compared with the static atomic layer deposition method, the efficiency this method is higher, cost is lower and process is also simpler.

According to some embodiments of the present disclosure, in step E1, the negative electrode plate of the secondary battery is in a coil shape, or has a length of >500 mm.

According to some embodiments of the present disclosure, in step E1, the isolation gas has a flow rate of 0.1-1000 SLM.

According to some embodiments of the present disclosure, in step E1, the metal precursor can be introduced in the form of vapor or carried by a carrier gas.

According to some embodiments of the present disclosure, in step E1, the metal precursor has a flow rate of 0.1-500 SLM.

According to some embodiments of the present disclosure, in step E1, the oxygen-containing reactant can be introduced directly or carried by a carrier gas.

According to some embodiments of the present disclosure, in step E1, the oxygen-containing reactant has a flow rate of 0.1-500 SLM.

According to some embodiments of the present disclosure, in step E2, the motion is at a speed of 0.01-300 m/min.

According to some embodiments of the present disclosure, in step E2, the electrode protective layer has a thickness of ≥0.1 nm.

According to some preferred embodiments of the present disclosure, in step E2, the obtained electrode protective layer has the thickness of ≥1 nm.

According to some preferred embodiments of the present disclosure, in step E2, the obtained electrode protective layer has the thickness of 0.1-20 nm.

According to some embodiments of the present disclosure, the atomic layer deposition method comprises the following steps:
A1. adsorbing the metal precursor on the surface of the negative electrode plate of the secondary battery in the chamber for atomic layer deposition;
A2. introducing the oxygen-containing reactant into the chamber in step A1 to make the oxygen-containing reactant react with the metal precursor; and
A3. repeating the steps A1 to A2, and performing cyclic deposition to form the electrode protective layer that has 1 to multi-layer laminated structure and is made of the metal oxide; and the metal oxide is a binary oxide.

According to some embodiments of the present disclosure, the preparation method is performed at a temperature of 50-350° C.

According to some preferred embodiments of the present disclosure, the preparation method is performed at the temperature of 100-200° C.

According to some embodiments of the present disclosure, in step A1, the metal precursor has a general formula of M-Rₙ, wherein M is a metal atom in the electrode protective layer, R is an organic group, and n is coordination number.

For M in the M-Rₙ, an example is as follows: for example, if the material of the electrode protective layer is CoO, M in the M-Rₙ is Co.

According to some preferred embodiments of the present disclosure, R is ethoxy.

According to some preferred embodiments of the present disclosure, in step A1, the method for introducing the metal precursor into the chamber is pulse introduction; wherein the one pulse introduction time (the time to complete a valve open-close cycle) is 0.1-5 s.

The number of pulse introduction required for metal precursor is 1-5 times.

According to some preferred embodiments of the present disclosure, in step A1, the adsorption further comprises maintaining the pressure for 1-10 s after each pulse introduction. The pressure maintaining can make the adsorption between the metal precursor and the negative electrode plate of the secondary battery more stable.

According to some preferred embodiments of the present disclosure, step A1 further comprises purging the chamber after completing pressure maintaining. The specific method of purging is to purge the chamber with N₂ for 30-90 s.

The reason for the need for purging after the step A1 is: after completing pressure maintaining, one part of the metal precursor in the chamber is adsorbed on the surface of the negative electrode plate of the secondary battery, and the other part of the metal precursor is dissociated in the chamber. In order to obtain a more even and dense electrode protective layer, it is necessary to purge the chamber to remove the metal precursor dissociated in the chamber.

According to some embodiments of the present disclosure, in step A2, the oxygen-containing reactant is at least one of water, hydrogen peroxide, ozone, and plasma oxygen.

The oxygen-containing reactant is used to provide oxygen source and reacts with the metal precursor adsorbed on the surface of the negative electrode plate of the secondary battery in step A1 to generate a metal oxide layer.

According to some embodiments of the present disclosure, in step A2, when the oxygen-containing reactant is not ozone, the introduction method is pulse introduction. The time for one pulse introduction (the time for completing one valve opening-closing cycle) is between 0.1-5 s.

According to some embodiments of the present disclosure, if the oxygen-containing reactant is O₃, the continuous introduction method can be further selected for 5-50 s each time, and the number of valve opening-closing cycle performed is 1-5 times.

According to some embodiments of the present disclosure, in step A2, reacting with the metal precursor further comprises maintaining the pressure for 1-10 s after each introduction of the oxygen-containing oxide. The number of plusing oxygen-containing reactant required is 1-5 times.

According to some embodiments of the present disclosure, the preparation method further comprises purging the ALD chamber for 60-180 s with N₂ after step A2. The purpose of purging is to remove oxygen-containing reactants that have not reacted with the metal precursor and have dissociated within the ALD chamber.

According to some embodiments of the present disclosure, in step A3, the number of cyclic deposition is 1-50 times.

The thickness of the electrode protective layer may be adjusted by adjusting the number of cyclic depositions in step A3, the greater the number of cycles, the thicker the electrode protective layer.

According to some embodiments of the present disclosure, the atomic layer deposition method comprises the following steps:
B1. adsorbing the first metal precursor on the surface of the negative electrode plate of the secondary battery in the chamber for atomic layer deposition;
B2. introducing the oxygen-containing reactant into the chamber in step B1 to make the oxygen-containing reactant react with the first metal precursor;
B3. introducing the second metal precursor into the chamber in step B2 to make the second metal precursor adsorb on the surface of the product obtained in step B2;
B4. introducing the oxygen-containing reactant into the chamber in step B3 to make the oxygen-containing reactant react with the second metal precursor; and
B5. repeating the steps B1 to B4, and performing cyclic deposition to form the electrode protective layer that has a 1 to multi-layer laminated structure and is made of the metal oxide; and the metal oxide is a ternary oxide.

According to some embodiments of the present disclosure, the methods of introducing the first metal precursor and the second metal precursor and the pressure maintaining time in steps B1 and B3 are the same as that of step A1.

According to some embodiments of the present disclosure, the atomic layer deposition method further comprises purging the reaction chamber between steps B1 to B5. The method corresponds to the purging method after steps A1 and A2.

According to some embodiments of the present disclosure, the reaction product of step B2 can undergo mutual penetration with the reaction product of step B4, resulting in a ternary oxide layer.

According to some embodiments of the present disclosure, in step B5, the number of cyclic deposition is 1-50 times.

According to some embodiments of the present disclosure, the atomic layer deposition method comprises the following steps:
C1. adsorbing the first metal precursor on the surface of the negative electrode plate of the secondary battery in the chamber for atomic layer deposition;
C2. introducing the oxygen-containing reactant into the chamber in step B1 to make the oxygen-containing reactant react with the first metal precursor;
C3. repeating the steps C1 to C2 to obtain a first metal oxide layer;
C4. introducing the second metal precursor into the chamber in step C3 to make the second metal precursor adsorb on the surface of the first metal oxide layer;
C5. introducing the oxygen-containing reactant into the chamber in step C4 to make the oxygen-containing reactant react with the second metal precursor;
C6. repeating the steps C4 to C5, and performing cyclic deposition to form the second metal oxide layer;
C7. cycling the steps C1 to C6, and performing cyclic deposition to form the electrode protective layer that has a multi-layer laminated structure and is made of the metal oxide.

According to some embodiments of the present disclosure, the methods of introducing the first metal precursor and the second metal precursor and the pressure maintaining time in steps C1 and C4 are the same as that of step A1.

According to some embodiments of the present disclosure, the method of introducing the oxygen-containing reactant and the pressure maintaining time in steps C2 and C5 are the same as that of step A2.

According to some embodiments of the present disclosure, the atomic layer deposition method further comprises purging the reaction chamber between the steps C1 to C7. The method corresponds to the purging method after steps A1 and A2.

According to some embodiments of the present disclosure, in step C7, the number of cyclic deposition is 1-50 times.

According to some embodiments of the present disclosure, in step C7, the obtained electrode protective layer is a laminated structure formed by multiple components; the thicknesses of the first metal oxide layer and the second metal oxide layer can be adjusted by adjusting the number of cyclic depositions in steps C3 and C6.

According to some embodiments of the present disclosure, the isolation gas is at least one of inert gas and nitrogen.

According to some embodiments of the present disclosure, the chemical vapor deposition method is one of an atmospheric pressure chemical vapor deposition method, a low pressure chemical vapor deposition method, and a plasma enhanced chemical vapor deposition method.

According to some embodiments of the present disclosure, the low pressure chemical vapor deposition method specifically comprises the following steps:
F1. placing the negative electrode plate of the secondary battery in a chamber of a low-pressure hot-wall chemical vapor deposition system, vacuumizing and cleaning; and
F2. introducing the metal precursor and the oxygen-containing reactant into the chamber in step F1, and reacting to obtain the electrode protective layer.

According to some embodiments of the present disclosure, in step F1, the vacuum degree of vaccumizing is ≤0.01 Torr.

According to some embodiments of the present disclosure, in step F1, the method of cleaning is purging the chamber with N₂ with a flow rate of 1000-5000 sccm for 15 min.

According to some preferred embodiments of the present disclosure, in step F1, the method of cleaning is purging the chamber with N₂ with the flow rate of about 2500 sccm for 15 min.

According to some embodiments of the present disclosure, in step F2, the temperature is 150-300° C.

According to some preferred embodiments of the present disclosure, in step F2, the temperature is about 200° C.

According to some embodiments of the present disclosure, in step F2, the metal precursor has a flow rate of 10-100 sccm.

According to some embodiments of the present disclosure, in step F2, the metal precursor has the flow rate of about 50 sccm.

According to some embodiments of the present disclosure, in step F2, the oxygen-containing reactant has a flow rate of 50-300 sccm.

According to some preferred embodiments of the present disclosure, in step F2, the oxygen-containing reactant has the flow rate of about 100 sccm.

According to some embodiments of the present disclosure, in step F2, the oxygen-containing reactant and metal precursor is introduced by a carrier gas. The carrier gas has a flow rate of 2500 sccm.

According to some embodiments of the present disclosure, in step F2, the pressure of reaction is at 10 mTorr to 100 mTorr, the time of reaction is 30 min.

According to some embodiments of the present disclosure, in step F2, the pressure of reaction is at about 0.04 Torr, the time of reaction is 30 min.

According to some embodiments of the present disclosure, the physical vapor deposition method is one of an evaporation method, a magnetron sputtering method, and a pulse laser deposition method.

According to some embodiments of the present disclosure, the magnetron sputtering method specifically comprises the following steps:
G1. placing the negative electrode plate of the secondary battery into a magnetron sputtering system, and vaccumizing;
G2. sputtering a transition layer on the surface of the negative electrode plate of the secondary battery in a protective gas atmosphere; and
G3. sputtering the electrode protective layer on the surface of the transition layer.

According to some embodiments of the present disclosure, in step G1, the pressure of vaccumizing is at 0.002 Torr.

According to some embodiments of the present disclosure, in step G2, Ar is selected as the protective gas, and the pressure is 0.01 Torr.

According to some embodiments of the present disclosure, in step G2, the material of the transition layer is at least one of titanium, chromium, aluminum, tungsten, titanium nitride and tungsten nitride.

According to some embodiments of the present disclosure, in step G2, the transition layer has a thickness of 0.1-50 nm.

According to some embodiments of the present disclosure, in step G2, the power supply of the transition layer is 50-300 W direct-current power supply in the sputtering parameters.

According to some embodiments of the present disclosure, in step G2, the bias voltage of the transition layer is-25 to 100V in the sputtering parameters.

According to some embodiments of the present disclosure, in step G2, the transition layer has the sputtering parameters are: the targeted raw material of the transition layer is sputtered using a direct-current power supply of about 150 W, the substrate is subjected to the bias voltage at about-50V and rotation at about 30 rad/min, and maintaining for about 3 min.

According to some embodiments of the present disclosure, in step G3, the sputtering parameters of the electrode protective layer are: a pure targeted material made of the metal oxide is sputtered by using 300 W radio frequency power supply, the substrate is subjected to the bias voltage at about −50V and rotation at about 30 rad/min, the maintaining time of sputtering is 30 min, and the electrode protective layer is deposited.

According to the third aspect of the present disclosure, provided is a negative electrode comprising an electrode protective layer, an active material, a binder, a conductive agent, and a current collector.

According to some embodiments of the present disclosure, the active material comprises at least one of graphite, graphene, carbon nanotubes, vapor grown carbon fibers, silicon carbon, silicon, lithium metal, sodium metal, and transition metal oxides.

It can be seen from the type of the active material that the negative electrode can be used in variety of secondary batteries; for example,
when the active material is one of graphite, graphene, carbon nanotubes, vapor grown carbon fibers, silicon carbon, silicon and transition metal oxides, the negative electrode can be used in at least one of lithium-ion battery, sodium ion battery, and potassium ion battery;
when the active material is lithium metal, the negative electrode can be used for lithium metal battery; and
when the active material is sodium metal, the negative electrode can be used for sodium metal battery.

Therefore, the negative electrode comprising the electrode protective layer provided by the present disclosure has a wide application range.

Due to the negative electrode according to the embodiments of the present disclosure uses the electrode protective layer mentioned above, it can have a more excellent effect of maintaining the specific capacity of the lithium battery.

According to some embodiments of the present disclosure, the binder includes, but is not limited to, polyvinylidene fluoride, poly(styrene-co-butadiene), and the like. The effect of the binder is forming a bonding between the active materials and between the active material and the current collector. That is, to help the active material form a coating layer on the surface of the current collector.

According to the fourth aspect of the present disclosure, there is provided a secondary battery comprising the negative electrode.

According to some embodiments of the present disclosure, the secondary battery further comprises a positive electrode corresponding to the negative electrode, and an electrolyte.

According to some embodiments of the present disclosure, the secondary battery is at least one of liquid battery and solid battery.

When the secondary battery is liquid battery, the secondary battery further comprises a separator.

According to some embodiments of the present disclosure, the secondary battery is at least one of lithium-ion battery, sodium-ion battery, potassium-ion battery, lithium metal battery, sodium metal battery, and potassium metal battery.

According to the secondary battery provided by the embodiment of the present disclosure, the cycle performance of the secondary battery can be further optimized, and the specific capacity of the battery quality can be more stably maintained after longer circulation.

According to the fifth aspect of the present disclosure, there is provided use of the secondary battery in the fields of 3C, energy storage and power batteries.

According to some embodiments of the present disclosure, the 3C field comprises at least one of computer product, communication product, and consumer electronics product.

According to some embodiments of the present disclosure, the field of power batteries comprises the field of new energy vehicles.

### BRIEF DESCRIPTION OF DRAWINGS

The following is a further explanation of the present disclosure in conjunction with the accompanying drawings and embodiments, wherein:

FIG. 1 is a schematic structural diagram of the commercial graphite negative electrode plate used in Example 1 according to the present disclosure;

FIG. 2 is a discharge specific capacity diagram of the lithium batteries consisting of the raw material of commercial graphite negative electrode plate used in the examples, and the negative electrode plates prepared in Example 3 and Comparative Example 1;

FIG. 3 is a discharge specific capacity diagram of the lithium batteries consisting of the raw material of commercial graphite negative electrode plate used in the examples, and the negative electrode plates prepared in Examples 2, 4-6 and 9 and Comparative Example 1;

FIG. 4 is a charge and discharge curves of the lithium batteries consisting of the raw material of commercial graphite negative electrode plate used in the examples, and the negative electrode plates prepared in Examples 2 and 4-5 at 50 cycles, 100 cycles and 150 cycles;

FIG. 5 is a rate performance diagram of the lithium batteries consisting of the raw material of commercial graphite negative electrode plate used in the examples and the negative electrode plates prepared in Examples 2 and 4-5.

### REFERENCE NUMBERS

100: current collector;
200: negative electrode coating layer; 210: active material; 220: binder.

### DETAILED DESCRIPTION

The concept of the present disclosure and the resulting technical effects will be clearly and completely described below in conjunction with examples, so that the aims, features, and effects of the present disclosure can be fully understood. It is clear that the described examples are merely some rather than all of examples of the present disclosure. All other examples obtained by those skilled in the art based on examples of the present disclosure without creative labor shall fall within the protection scope of the present disclosure.

In the description of the present disclosure, the description with reference to the terms “one embodiment”, “some embodiments”, “exemplary embodiment”, “example”, “specific example”, “some examples” etc. refers to the particular features, structures, materials or characteristics described in combination with the embodiment or example are included in at least one embodiment or example of the present disclosure. In this specification, the exemplary expression of above terms does not necessarily refer to the same embodiments or examples. Furthermore, the specific features, structures, materials, or characteristics described can be combined in any suitable manner in any one or more embodiments or examples.

Unless otherwise specified, the commercial graphite negative electrode plate used in the embodiments of the present disclosure comprises a current collector 100 and a negative electrode coating 200 coated thereon. It comprises an active material graphite 210 and a binder 220 in negative electrode coating layer 200, which is purchased from Canrd, wherein the plate number is SM0201, the active material ratio is 95.7%, the material gram capacity: 330 mAh/g (0.005-2.0 V), the current collector has a thickness of 8 μm, and the coating surface density is about 5.8 mg/cm² (at different positions, the surface density after compaction may fluctuate within a certain range). The commercial graphite negative electrode plate does not be rolled. Specific examples of the present disclosure are described in detail below.

### Example 1

This example prepares an electrode protective layer with a material of CoₓO (x=0.75-1), and above electrode protective layer is attached to a commercial graphite negative electrode plate, and the preparation method is atomic layer deposition method, which comprises the specific steps of:
H1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the chamber;
H2. a metal precursor bis(2,2,6,6,-tetramethyl-3,5-heptanedioate)cobalt was pulsed into a reaction chamber at 150° C. The valve opening and closing time: 1 s. After the reaction chamber pressure reached 15 Torr, the pressure was maintained for 5 s. The total number of pulse in this step was 1;
H3. 2000 sccm of N₂ was introduced into the chamber of step H2, and purged for 30 s, wherein the bis(2,2,6,6,-tetramethyl-3,5-heptanedioate)cobalt was adsorbed on the surface of the commercial graphite negative electrode;
H4. an oxygen-containing reactant ozone (O₃) was introduced into the reaction chamber, when the pressure of the chamber reached 5 Torr, time of maintaining: 15 s, and numbers of valve opening and closing was 5, allowing ozone to fully react with bis(2,2,6,6,-tetramethyl-3,5-heptanedioate)cobalt in step H3;
H5. 2000 sccm of N₂ was introduced into the chamber in step H4 and purged for 60 s;
H6. steps H2-H5 were cycled for 40 times to obtain the electrode protective layer with a thickness of 1.6 nm.

The CoₓO obtained in this example represents a non-stoichiometric cobalt oxide, and since the valence of element such as Co etc can not be controlled in ALD chemical reaction process, non-stoichiometric oxides are often obtained. However, ALD tends to produce low valence compounds, x is thus between 0.75-1, and x fluctuates within the above range without affecting the performance of the resulting negative electrode plate.

By proportionally adjusting the cycle number in step H6, this example also obtained electrode protective layers made of CoₓO (x=0.75-1) with thicknesses of 1 nm, 5 nm and 10 nm, respectively.

### Example 2

This example prepares an electrode protective layer with a material of FeₓO (x=0.67-1), and above electrode protective layer is attached to a commercial graphite negative electrode plate, and the preparation method is atomic layer deposition method, which comprises the specific steps of:
H1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
H2. a metal precursor ferrocene was placed into a reaction chamber at 200° C. The valve opening and closing time: 1 s. After the reaction chamber pressure reached 15 Torr, the pressure was maintained for 10 s. The total number of pulse in this step was 1;
H3. 2000 sccm of N₂ was introduced into the chamber of step H2, and purged for 60 s, wherein the ferrocene was adsorbed on the surface of the commercial graphite negative electrode;
H4. an oxygen-containing reactant ozone (O₃) was introduced into the reaction chamber, when the pressure of the chamber reached 5 Torr, time of maintaining: 15 s, and numbers of valve opening and closing were 5 times, allowing ozone to fully react with ferrocene in step H3;
H5. 2000 sccm of N₂ was introduced into the chamber in step H4 and purged for 120 s; H6. steps H2-H5 were cycled for 30 times.

FeₓO obtained in this example represents non-stoichiometric iron oxide, the reason of formation refers to Example 1, and x fluctuates between 0.67 and 1 without affecting the performance of the obtained negative electrode plate.

### Example 3

This example prepares an electrode protective layer with a material of CoₓSnO₂₊ₓ (0<x<2), and above electrode protective layer is attached to a commercial graphite negative electrode plate, and the preparation method is atomic layer deposition method, which comprises the specific steps of:
I1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
I2. a metal precursor tetrakis(diethylamine)tin was pulsed into a reaction chamber at 150° C. The time of valve opening and closing: 1 s. After the reaction chamber pressure reached 15 Torr, the pressure was maintained for 5 s. The total number of pulse in this step was 1;
I3. 2000 sccm of N₂ was introduced into the chamber of step H2, and purged for 30 s, wherein the tetrakis(diethylamine)tin was adsorbed on the surface of the commercial graphite negative electrode;
I4. an oxygen-containing reactant ozone (O₃) was introduced into the reaction chamber, when the pressure of the chamber reached 5 Torr, time of maintaining: 20 s, and numbers of valve opening and closing were 5 times, allowing ozone to fully react with tetrakis(diethylamine)tin;
I5. 2000 sccm of N₂ was introduced into the chamber in step I4 and purged for 90 s;
I6. a metal precursor bis(2,2,6,6,-tetramethyl-3,5-heptanedioate)cobalt was pulsed into the reaction chamber at 150° C. The valve opening and closing time was 1 s. After the reaction chamber pressure reached 15 Torr, the pressure was maintained for 5 s, and the total number of pulse was 1 time;
I7. 2000 sccm of N₂ was introduced into the chamber in step I6 and purged for 30 s;
18. the reactant ozone (O₃) was introduced into the reaction chamber, when the pressure of the chamber reached 5 Torr, maintaining for 15 s, and numbers of valve opening and closing were 5 times, allowing ozone to fully react with bis(2,2,6,6,-tetramethyl-3,5-heptanedioate)cobalt in step I6, and the reaction product obtained in this step was fully diffused with the reaction product obtained in step I4;
I9. 2000 sccm of N₂ was introduced into the chamber in step I8 and purged for 60 s;
I10. steps I2-I9 were cycled for 20 times to obtain the electrode protective layer with a thickness of 3.2 nm.

The CoₓSnO₂₊ₓ obtained in this example represents non-stoichiometric cobalt stannate, the reason of formation refers to Example 1, and x fluctuates between 0 and 2 without affecting the performance of the obtained negative electrode plate.

By controlling the cycle times in step I10 in an equal proportion, the electrode protective layers made of CoₓSnO₂₊ₓ (0<x<2) with thicknesses of 1 nm, 5 nm and 10 nm are respectively prepared and obtained in this example.

### Example 4

This example prepares an electrode protective layer with a material of CuMnₓO₂ (x=0.67-1), and above electrode protective layer is attached to a commercial graphite negative electrode plate, and the preparation method is an atomic layer deposition method, which comprises the specific steps of:
I1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
I2. a metal precursor copper acetylacetonate was pulsed into a reaction chamber at 200° C. The valve opening and closing time: 1 s. After the reaction chamber pressure reached 15 Torr, the pressure was maintained for 5 s. The total number of pulses in this step was 1;
I3. 2000 of sccm N₂ was introduced into the chamber in step I2, and purged for 30 s, wherein copper acetylacetonate was adsorbed on the surface of the commercial graphite negative electrode;
I4. an oxygen-containing reactant ozone (O₃) was introduced into the reaction chamber, when the pressure of the chamber reached 5 Torr, time of maintaining: 15 s, and the numbers of valve opening and closing were 5 times, and allowing ozone to fully react with copper acetylacetonate in step I3;
I5. 2000 sccm of N₂ was introduced into the chamber in step I4 and purged for 90 s;
I6. a metal precursor tris(2,2,6,6-tetramethyl-3,5-heptanedione)manganese was pulsed into the reaction chamber at 150° C. The time of valve opening and closing was 1 s. After the reaction chamber pressure reached 15 Torr, the pressure was maintained for 10 s. The total number of pulse in this step was 1;
I7. 2000 sccm of N₂ was introduced into the chamber in step I6, and purged for 30 s, wherein the tris(2,2,6,6-tetramethyl-3,5-heptanedione)manganese was adsorbed on the surface of the product obtained in step I5;
I8. the reactant ozone (O₃) were introduced into the reaction chamber, when the pressure of the chamber reached 5 Torr, maintaining for 10 s, allowing ozone to fully react with tris(2,2,6,6-tetramethyl-3,5-heptanedione)manganese in step I7, for 5 times, and the product obtained in this step was fully diffused with the reaction product obtained in step I4;
I9. 2000 sccm of N₂ was introduced into the chamber in step I8 and purged for 60 s;
I10. steps I2-I9 were cycled for 20 times to obtain the electrode protective layer with a thickness of 2 nm.

The CuMnₓO₂ obtained in this example represents non-stoichiometric copper manganate, the reason of formation refers to Example 1, and x fluctuates between 0.67 and 1, without affecting the performance of the obtained negative electrode plate.

By controlling the cycle number of step I10 in an equal proportion, this example also obtained electrode protective layers with thicknesses of 1 nm, 5 nm and 10 nm, respectively.

### Example 5

This example prepares an electrode protective layer with a material of CoₓO (x=0.75-1)/Fe_{y}O (y=0.67-1) and having a nano-laminated structure, and above electrode protective layer is attached to a commercial graphite negative electrode plate, and the preparation method is atomic layer deposition method, which comprises the specific steps of:
J1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
J2. a first metal precursor bis(2,2,6,6,-tetramethyl-3,5-heptanedioate)cobalt was pulsed into a reaction chamber at 150° C. The time of valve opening and closing: 1 s, after the reaction chamber pressure reached 15 Torr, the pressure was maintained for 5 s. The total number of pulse was 1;
J3. 2000 of sccm N₂ was introduced into the chamber in step J2, and purged for 30 s, wherein a layer of bis(2,2,6,6,-tetramethyl-3,5-heptanedioate)cobalt was adsorbed on the surface of the commercial graphite negative electrode;
J4. an oxygen-containing reactant ozone (O₃) was introduced into the reaction chamber, when the pressure of the chamber reached 5 Torr, maintaining for 15 s, for 5 times;
J5. 2000 sccm of N₂ was introduced into the chamber in step J4 and purged for 60 s;
J6. steps J2-J5 were cycled for 5 times to obtain a CoₓO layer;
J7. a second metal oxide ferrocene was pulsed into the reaction chamber at 200° C., wherein the time of valve opening and closing was 1 s, after the pressure reached 15 Torr, the pressure was maintained for 10 s, and the total number of pulse was 1;
J8. 2000 sccm of N₂ was introduced into the chamber in step J7 and purged for 60 s;
J9. an oxygen-containing reactant and ozone (O₃) were introduced into the reaction chamber, when the pressure of the chamber reached 5 Torr, maintaining for 15 s, for 5 times;
J10. 2000 sccm of N₂ was introduced and purged for 120 s;
J11. steps J7-J10 were cycled for 3 times to obtain a FeₓO layer;
J12. steps J2-J10 were cycled for 5 times to obtain an electrode protective layer with a laminated structure in which the CoₓO layer and FeₓO layer were alternately formed.

CoₓO (x=0.75-1)/Fe_{y}O (y=0.67-1) prepared in this example represents a laminated structure formed by laminating non-stoichiometric cobalt oxide and iron oxide, and the formation reason of formation refers to Example 1, and x and y fluctuate within the above range without affecting the performance of the obtained negative electrode plate.

### Example 6

This example prepares an electrode protective layer with a material of CuO, and above electrode protective layer is attached to a commercial graphite negative electrode plate, and the preparation method is low-pressure hot-wall chemical vapor deposition, which comprises the specific steps of:
L1. a commercial graphite negative electrode plate was placed into a chamber of low-pressure hot-wall chemical vapor deposition system, vacuumizing by using a mechanical pump to reduce the air pressure of the chamber to 0.01 Torr, then introducing N₂ (2500 sccm) was introduced to clean the chamber for 15 min;
L2. 50 sccm of copper acetylacetonate and 100 sccm of oxygen were introduced into the reaction chamber at 200° C., wherein the carrier gas was 2500 sccm of N₂, the pressure in the reaction chamber was maintained at 0.04 Torr, the reaction time was 30 min, and a CuO film was deposited on the surface of the negative electrode plate.

### Example 7

This example prepares an electrode protective layer with a material of Co₂SnO₄, and above electrode protective layer is attached to a commercial graphite negative electrode plate, and the preparation method is magnetron sputtering method, which comprises the specific steps of:
M1. the commercial graphite negative electrode plate was transferred into a magnetron sputtering system, and the air pressure of chamber in system was reduced to 0.002 Torr by using a mechanical pump and a molecular pump;
M2. 80 sccm of Ar was introduced, and the air pressure in the system chamber was raised to 0.01 Torr. a pure titanium target material was sputtered by using a 150 W direct current power supply. The bias voltage was applied to the substrate at −50V, and rotated at 30 rad/min for 3 min, and a titanium transition layer was deposited on the surface of the negative electrode plate;
M3. a pure Co₂SnO₄ target material was sputtered by using a 300 W radio frequency power supply. The bias voltage was applied to the substrate at −50V, and rotated at 30 rad/min. The sputtering time was 30 min, and a coating layer Co₂SnO₄ was deposited.

### Example 8

This example prepares an electrode protective layer with a material of FeₓO (x=0.67-1), and above electrode protective layer is attached to a commercial graphite negative electrode plate, and the preparation method is roll-to-roll atomic layer deposition method, which comprises the specific steps of:
P1. a negative electrode plate coil stock with a width of 1000 mm and a length of 1000 m was placed in the chamber of an atomic layer deposition system, vacuumizing the system to 0.05 Torr. The inert isolation gas with a flow rate of 400 SLM, the iron source precursor gas used for FeₓO (x=0.67-1) electrode protective layer with a flow rate of 200 SLM and 500 mg/L ozone gas used for electrode protective layer material with a flow rate of 200 SLM were sequentially or simultaneously introduced into the atomic layer deposition chamber;
P2. The moving mechanism was started to enable the electrode plate to be deposited to pass through the inner cavity deposition area of five cycles in two directions at the speed of 50 m/min for four times;
P3. when all the negative electrode plates had moved forward, the flushing gas, the iron source precursor gas and ozone gas were turned off. The heating was turned off, and air was filled back. A winding device was opened to move the graphite negative electrode plate after completing the deposition processing.

### Example 9

This example prepares an electrode protective layer with a material of In₂O₃, and above electrode protective layer is attached to a commercial graphite negative electrode plate, and the preparation method is atomic layer deposition method, which comprises the specific steps of:
H1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
H2. a metal precursor trimethylindium was pulsed into a reaction chamber at 150° C., wherein the time of valve opening and closing: 0.5 s, after the reaction chamber pressure reached 10 Torr, the pressure was maintained for 5 s, and the total number of pulse in this step was 1;
H3. 2000 sccm of N₂ was introduced into the chamber of the step H2, and purged for 30 s, wherein the trimethylindium was adsorbed on the surface of the commercial graphite negative electrode;
H4. an oxygen-containing reactant and water (H₂O) were introduced into the reaction chamber, when the pressure of the chamber reached 1 Torr, time of maintaining: 1 s, and numbers of valve opening and closing were 5 times, allowing H₂O to fully react with trimethylindium in step H3;
H5. 2000 sccm of N₂ was introduced into the chamber in step H4 and purged for 20 s;
H6. steps H2-H5 were cycled for 25 times to obtain the electrode protective layer with a thickness of 1 nm.

By controlling the cycle number of step H6 in an equal proportion, this example also prepared and obtained electrode protective layers with thicknesses of 5 nm and 10 nm, respectively.

### Example 10

This example prepares an electrode protective layer with a material of MnₓO, and this electrode protective layer is attached to a commercial graphite negative electrode plate, and the preparation method is atomic layer deposition method, which comprises the specific steps of:
H1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
H2. a metal precursor tris(2,2,6,6-tetramethyl-3,5-heptanedione)manganese was pulsed into a reaction chamber at 150° C. The time of valve opening and closing was 1 s, after the reaction chamber pressure reached 15 Torr, the pressure was maintained for 10 s, and the total number of pulse in this step was 1;
H3. 2000 sccm of N₂ was introduced into the chamber of step H2, and purged for 30 s, wherein the tris(2,2,6,6-tetramethyl-3,5-heptanedione)manganese was adsorbed on the surface of the commercial graphite negative electrode;
H4. the reactant ozone (O₃) was introduced into the reaction chamber, when the pressure of the chamber reached 5 Torr, maintaining for 10 s, allowing ozone to fully react with tris(2,2,6,6-tetramethyl-3,5-heptanedione)manganese in step H3, for 5 times;
H5. 2000 sccm of N₂ was introduced into the chamber in step H4 and purged for 20 s;
H6. steps H2-H5 were cycled for 20 times.

### Example 11

This example prepares an electrode protective layer with a material of NiO, and above electrode protective layer is attached to a commercial graphite negative electrode plate, and the preparation method is atomic layer deposition method, which comprises the specific steps of:
H1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
H2. a metal precursor bis(dimethylamino-2-propoxy)nickel was pulsed into the reaction chamber at 150° C. The valve opening and closing time was 1 s, after the reaction chamber pressure reached 15 Torr, the pressure was maintained for 10 s, and the total number of pulse in this step was 1;
H3. 2000 sccm of N₂ was introduced into the chamber of step H2, and purged for 30 s, wherein the bis(dimethylamino-2-propoxy)nickel was adsorbed on the surface of the commercial graphite negative electrode;
H4. the reactant ozone (O₃) was introduced into the reaction chamber, when the pressure of the chamber reached 5 Torr, maintaining for 10 s, allowing ozone to fully react with bis(dimethylamino-2-propoxy)nickel in step H3, for 5 times;
H5. 2000 sccm of N₂ was introduced into the chamber in step H4 and purged for 20 s;
H6. steps H2-H5 were cycled for 20 times.

### Example 12

This example prepares an electrode protective layer with a material of CuO, and above electrode protective layer is attached to a commercial graphite negative electrode plate, and the preparation method is atomic layer deposition method, which comprises the specific steps of:
H1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
H2. a second metal precursor copper acetylacetonate was pulsed into the reaction chamber at 150° C. The time of valve opening and closing: 1 s, after the reaction chamber pressure reached 15 Torr, the pressure was maintained for 10 s, and the total number of pulse in this step is 1;
H3. 2000 of sccm N₂ was introduced into the chamber in step H2, and pulsed for 30 s, wherein copper acetylacetonate was adsorbed on the surface of the commercial graphite negative electrode;
H4. the reactant ozone (O₃) was introduced into the reaction chamber, when the pressure of the chamber reached 5 Torr, maintaining for 10 s, allowing ozone to fully react with copper acetylacetonate in step H3, for 5 times;
H5. 2000 sccm of N₂ was introduced into the chamber in step H4 and purged for 20 s;
H6. steps H2-H5 were cycled for 25 times.

### Example 13

This example prepares an electrode protective layer with a material of ZnO, and above electrode protective layer is attached to a commercial graphite negative electrode plate, and the preparation method is atomic layer deposition method, which comprises the specific steps of:
H1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
H2. a metal precursor diethyl zinc was pulsed into a reaction chamber at 150° C. The time of valve opening and closing: 0.5 s, after the reaction chamber pressure reached 1 Torr, the pressure was maintained for 5 s, and the total number of pulse in this step is 1;
H3. 2000 sccm of N₂ was introduced into the chamber of step H2, and purged for 30 s, wherein the diethyl zinc was adsorbed on the surface of the commercial graphite negative electrode;
H4. an oxygen-containing reactant and water (H₂O) were introduced into the reaction chamber, when the pressure of the chamber reached 1 Torr, time of maintaining: 1 s, number of valve opening and closing was 1 time, allowing H₂O to fully react with diethyl zinc in step H3;
H5. 2000 sccm of N₂ was introduced into the chamber in step H4 and purged for 20 s;
H6. steps H2-H5 were cycled for 15 times.

### Example 14

This example prepares an electrode protective layer with a material of Nb₂O₅, and above electrode protective layer is attached to a commercial graphite negative electrode plate, and the preparation method is atomic layer deposition method, which comprises the specific steps of:
H1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
H2. a metal precursor niobium pentaethoxide was pulsed into a reaction chamber at 150° C. The time of valve opening and closing: 2 s, after the reaction chamber pressure reached 1 Torr, the pressure was maintained for 5 s, and the total number of pulse in this step is 1;
H3. 2000 sccm of N₂ was introduced into the chamber of the step H2, and purged for 30 s, wherein the niobium pentaethoxide was adsorbed on the surface of the commercial graphite negative electrode;
H4. an oxygen-containing reactant and water (H₂O) were introduced into the reaction chamber, when the pressure of the chamber reached 1 Torr, time of maintaining: 5 s, number of valve opening and closing was 1 time, allowing H₂O to fully react with niobium pentaethoxide in step H3;
H5. 2000 sccm of N₂ was introduced into the chamber in step H4 and purged for 20 s;
H6. steps H2-H5 were cycled for 30 times.

### Example 15

This example prepares an electrode protective layer with a material of CoₓO (x=0.75-1), and above electrode protective layer is attached to a commercial graphite negative electrode plate, and the preparation method is roll-to-roll atomic layer deposition method, which comprises the specific steps of:
P1. a negative electrode plate coil stock with a width of 1000 mm and a length of 1000 m was placed in a chamber of an atomic layer deposition system, vacuumizing the system to 0.05 Torr. The inert isolation gas with a flow rate of 400 SLM, mixed gas of bis(2,2,6,6,-tetramethyl-3,5-heptanedioate)cobalt source precursor and nitrogen carrier gas used by a CoₓO (x=0.75-1) electrode protective layer with a flow rate of 200 SLM, and 500 mg/L ozone gas used by an electrode protective layer material with a flow rate of 200 SLM were sequentially or simultaneously introduced into the atomic layer deposition chamber;
P2. The moving mechanism was started to enable the electrode plate to be deposited to pass through the inner cavity deposition area of five cycles in two directions at the speed of 10 m/min for four times;
P3. when all the negative electrode plates had moved forward, the flushing gas, the cobalt source precursor gas and ozone gas were turned off. The heating was turned off, and air was filled back. A winding device was opened to move the graphite negative electrode plate after completing the deposition processing.

### Example 16

This example prepares an electrode protective layer with a material of In₂O₃, and above electrode protective layer is attached to a commercial graphite negative electrode plate, and the preparation method is roll-to-roll atomic layer deposition method, which comprises the specific steps of:
P1. a negative electrode plate coil stock with a width of 1000 mm and a length of 1000 m was placed in a chamber of an atomic layer deposition system, vacuumizing the system to 0.05 Torr. The inert isolation gas with a flow rate of 400 SLM, the mixed gas of indium source precursor and nitrogen carrier gas used by a In₂O₃ electrode protective layer with a flow rate of 200 SLM, and the mixed gas of water vapor and nitrogen carrier gas used by an electrode protective layer material with a flow rate of 200 SLM were sequentially or simultaneously introduced into the atomic layer deposition chamber;
P2. The moving mechanism was started to enable the electrode plate to be deposited to pass through the inner cavity deposition area of five cycles in two directions at the speed of 10 m/min for four times;
P3. when all the negative electrode plates had moved forward, the flushing gas, the indium source precursor gas and ozone gas were turned off. The heating was turned off, and air was filled back. A winding device was opened to move the graphite negative electrode plate after completing the deposition processing.

### Example 17

This example prepares an electrode protective layer with a material of Li₄Ti₅O₁₂, and above electrode protective layer is attached to a commercial graphite negative electrode plate, and the preparation method is atomic layer deposition method, which comprises the specific steps of:
I1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
I2. a metal precursor tert-butyl lithium was pulsed into a reaction chamber at 200° C. The time of valve opening and closing: 1 s, after the reaction chamber pressure reached 15 Torr, the pressure was maintained for 5 s, and the total number of pulse in this step is 1;
I3. 2000 sccm of N₂ was introduced into the chamber of step H2, and purged for 30 s, wherein the tert-butyl lithium was adsorbed on the surface of the commercial graphite negative electrode;
I4. an oxygen-containing reactant and water (H₂O) were introduced into the reaction chamber, when the pressure of the chamber reached 5 Torr, time of maintaining: 15 s, for 5 times, allowing water to fully react with tert-butyl lithium in step I3;
I5. 2000 sccm of N₂ was introduced into the chamber in step I4 and purged for 90 s;
I6. a metal precursor titanium tetraisopropoxide was pulsed into a reaction chamber at 150° C. The time of valve opening and closing: 1 s, after the reaction chamber pressure reached 15 Torr, the pressure was maintained for 10 s. The total number of pulse in this step was 1;
I7. 2000 sccm of N₂ was introduced into the chamber in step I6, and purged for 30 s, wherein the titanium tetraisopropoxide was adsorbed on the surface of the product obtained in step I5;
I8. the reactant water (H₂O) was introduced into the reaction chamber, when the pressure of the chamber reached 5 Torr, maintaining for 10 s, allowing water to fully react with titanium tetraisopropoxide in step I7, for 5 times, and the product obtained in this step was fully diffused with the reaction product obtained in step I4;
I9. 2000 sccm of N₂ was introduced into the chamber in step I8 and purged for 60 s;
I10. steps I2-I9 were cycled for 20 times.

### Example 18

This example prepares an electrode protective layer with a material of TiNb₂O₇, and above electrode protective layer is attached to a commercial graphite negative electrode plate, and the preparation method is atomic layer deposition method, which comprises the specific steps of:
I1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
I2. a metal precursor titanium tetraisopropoxide was placed into a reaction chamber at 200° C. The valve opening and closing time: 1 s. After the reaction chamber pressure reached 15 Torr, the pressure was maintained for 5 s, and the total number of pulse in this step was 1;
I3. 2000 of sccm N₂ was introduced into the chamber in step I2, and purged for 30 s, wherein titanium tetraisopropoxide was adsorbed on the surface of the commercial graphite negative electrode;
I4. an oxygen-containing reactant and water (H₂O) were introduced into the reaction chamber, when the pressure of the chamber reached 5 Torr, time of maintaining: 15 s, number of valve opening and closing was 5 times, allowing water to fully reacted with the titanium tetraisopropoxide in step I3;
I5. 2000 sccm of N₂ was introduced into the chamber in step I4 and purged for 90 s;
I6. a metal precursor niobium pentaethoxide was pulsed into the reaction chamber at 150° C. The valve opening and closing time: 1 s, after the reaction chamber pressure reached 15 Torr, the pressure was maintained for 10 s, and the total number of pulse was 1 time;
I7. 2000 sccm of N₂ was introduced into the chamber in step I6, and purged for 30 s, wherein the niobium pentaethoxide was adsorbed on the surface of the product obtained in step I5;
I8. the reactant water (H₂O) was introduced into the reaction chamber, when the pressure of the chamber reached 5 Torr, maintaining for 10 s, allowing water to fully react with niobium pentaethoxide in step I7, for 5 times, and the product obtained in this step was fully diffused with the reaction product obtained in step I4;
I9. 2000 sccm of N₂ was introduced into the chamber in step I8 and purged for 60 s;
I10. steps I2-I9 were cycled for 20 times.

### Example 19

This example prepares an electrode protective layer with a material of CoSb₂O₆, and above electrode protective layer is attached to a commercial graphite negative electrode plate, and the preparation method is atomic layer deposition method, which comprises the specific steps of:
I1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
I2. a metal precursor bis(2,2,6,6,-tetramethyl-3,5-heptanedioate)cobalt was pulsed into a reaction chamber at 200° C. The valve opening and closing time: 1 s, after the reaction chamber pressure reached 15 Torr, the pressure was maintained for 5 s, and the total number of pulse in this step was 1;
I3. 2000 sccm of N₂ was introduced into the chamber of step I2, and purged for 30 s, wherein the bis(2,2,6,6,-tetramethyl-3,5-heptanedioate)cobalt was adsorbed on the surface of the commercial graphite negative electrode;
I4. an oxygen-containing reactant and water (H₂O) were introduced into the reaction chamber, when the pressure of the chamber reached 5 Torr, time of maintaining: 15 s, number of valve opening and closing was 5 times, allowing water to fully react with bis(2,2,6,6,-tetramethyl-3,5-heptanedioate)cobalt in step I3;
I5. 2000 sccm of N₂ was introduced into the chamber in step I4 and purged for 90 s;
I6. a metal precursor antimony pentachloride was pulsed into the reaction chamber at 150° C. The valve opening and closing time: 1 s, after the reaction chamber pressure reached 15 Torr, the pressure was maintained for 10 s, and the total number of pulse was 1 time;
I7. 2000 sccm of N₂ was introduced into the chamber in step I6, and purged for 30 s, wherein the niobium pentaethoxide was adsorbed on the surface of the product obtained in step I5;
I8. the reactant water (H₂O) was introduced into the reaction chamber, when the pressure of the chamber reached 5 Torr, maintaining for 10 s, allowing water to fully react with antimony pentachloride in step I7, for 5 times, and the product obtained in this step was fully diffused with the reaction product obtained in step I4;
I9. 2000 sccm of N₂ was introduced into the chamber in step I8 and purged for 60 s;
I10. steps I2-I9 were cycled for 20 times.

### Example 20

This example prepares an electrode protective layer with a material of CoₓO/In₂O₃ (x=0.75-1) and having a nano-laminated structure, and above electrode protective layer is attached to a commercial graphite negative electrode plate, and the preparation method is atomic layer deposition method, which comprises the specific steps of:
J1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
J2. a first metal precursor bis(2,2,6,6,-tetramethyl-3,5-heptanedioate)cobalt was pulsed into a reaction chamber at 150° C. The valve opening and closing time: 1 s, after the reaction chamber pressure reached 15 Torr, the pressure was maintained for 5 s, and the total number of pulse is in this step was 1 time;
J3. 2000 of sccm N₂ was introduced into the chamber in step J2, and purged for 30 s, wherein a layer of bis(2,2,6,6,-tetramethyl-3,5-heptanedioate)cobalt was adsorbed on the surface of the commercial graphite negative electrode;
J4. an oxygen-containing reactant ozone (O₃) was introduced into the reaction chamber, when the pressure of the chamber reached 5 Torr, maintaining for 15 s, for 5 times;
J5. 2000 sccm of N₂ was introduced into the chamber in step J4 and purged for 60 s;
J6. steps J2-J5 were cycled for 5 times to obtain a CoₓO layer;
J7. a second metal oxide source trimethylindium was pulsed into the reaction chamber at 150° C. The valve opening and closing time: 1 s, after the pressure reached 15 Torr, the pressure was maintaining for 10 s, and the total number of pulse was 1;
J8. 2000 sccm of N₂ was introduced into the chamber in step J7 and purged for 60 s;
J9. an oxygen-containing reactant ozone (O₃) was introduced into the reaction chamber, when the pressure of the chamber reached 5 Torr, maintaining for 15 s, for 5 times;
J10. 2000 sccm of N₂ was introduced and purged for 120 s;
J11. steps J7-J10 were cycled for 3 times to obtain the In₂O₃ layer;
J12. steps J2-J10 were cycled for 5 times to obtain an electrode protective layer with a laminated structure in which the CoₓO layer and In₂O₃ layer are alternately formed.

CoₓO/In₂O₃ (x=0.75-1) prepared in this example represents a laminated structure formed by laminating non-stoichiometric cobalt oxide and iron oxide, and the reason of formation refers to Example 1, and x fluctuates within the above range without affecting the performance of the obtained negative electrode plate.

### Example 21

This example prepares an electrode protective layer with a material of In₂O₃/ZnO and having a nano-laminated structure, and above electrode protective layer is attached to a commercial graphite negative electrode plate, and the preparation method is atomic layer deposition method, which comprises the specific steps of:
J1. a commercial graphite negative electrode plate was palced into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the cavity;
J2. a first metal precursor trimethylindium was pulsed into the reaction chamber at 150° C. The valve opening and closing time: 1 s, after the reaction chamber pressure reached 15 Torr, the pressure was maintained for 5 s, and the total number of pulse was 1;
J3. 2000 sccm of N₂ was introduced into the chamber of step J2, and purged for 30 s, wherein the a trimethylindium layer was adsorbed on the surface of the commercial graphite negative electrode;
J4. an oxygen-containing reactant ozone (O₃) was introduced into the reaction chamber, when the pressure of the chamber reached 5 Torr, maintaining for 15 s, for 5 times;
J5. 2000 sccm of N₂ was introduced into the chamber in step J4 and purged for 60 s;
J6. steps J2-J5 were cycled for 5 times to obtain a In₂O₃ layer;
J7. a second metal oxide source diethyl zinc was pulsed into the reaction chamber at 150° C. The valve opening and closing time was 1 s, after the pressure reached 15 Torr, the pressure was maintained for 10 s, and the total number of pulse was 1;
J8. 2000 sccm of N₂ into the chamber in the step J7 for purging for 60 s;
J9. introducing an oxygen-containing reactant ozone (O₃) was introduced into the reaction chamber, when the pressure of the chamber reached 5 Torr, maintaining for 15 s, for 5 times;
J10. 2000 sccm of N₂ was introduced and purged for 120 s;
J11. steps J7-J10 were cycled for 3 times to obtain the ZnO layer;
J12. steps J2-J10 were cycled for 5 times to obtain an electrode protective layer with a laminated structure in which the In₂O₃ layer and ZnO layer are alternately formed.

The In₂O₃/ZnO prepared in this example is a laminated structure formed by laminating non-stoichiometric indium oxide and zinc oxide, and the reason of formation refers to Example 1.

### Example 22

This example prepares an electrode protective layer with a material of CoₓSnO₂₊ₓ, and above electrode protective layer is attached to a commercial graphite negative electrode plate, and the preparation method is low-pressure hot-wall chemical vapor deposition, which comprises the specific steps of:
L1. a commercial graphite negative electrode plate was placed into a chamber of a low-pressure hot-wall chemical vapor deposition system, vacuumizing by using a mechanical pump to reduce the air pressure of the chamber to 0.01 Torr, then N₂ (2500 sccm) was introduced to clean the chamber for 15 min;
L2. 50 sccm of a metal precursor tetrakis(diethylamine)tin, 50 sccm of bis(2,2,6,6,-tetramethyl-3,5-heptanedioate)cobalt, and 100 sccm of oxygen were introduced into the reaction chamber at 150° C. The carrier gas was 2500 sccm of N₂, the pressure in the reaction chamber was maintained at 0.04 Torr, the reaction time was 30 min, and the CoₓSnO₂₊ₓ was deposited on the surface of the negative electrode plate.

### Example 23

This example prepares an electrode protective layer with a material of CuO, and this electrode protective layer is attached to a commercial graphite negative electrode plate, and the preparation method is magnetron sputtering method, which comprises the specific steps of:
M1. the commercial graphite negative electrode plate was transferred into a magnetron sputtering system, and the air pressure of chamber in system was reduced to 0.002 Torr by using a mechanical pump and a molecular pump;
M2. 80 sccm of Ar was introduced, and the air pressure in the system chamber was raised to 0.01 Torr; a CuO target material material was sputtered by using a 150 W alternating current power supply. The bias voltage was applied to the substrate at −50V, and rotated at 20 rad/min for 3 min, and a CuO coating layer was deposited on the surface of the negative electrode plate.

### Comparative Example 1

This comparative example prepares an electrode protective layer with a material of Al₂O₃, and above electrode protective layer is attached to a commercial graphite negative electrode plate, and the preparation method is atomic layer deposition method, which comprises the specific steps of:
A1. a commercial graphite negative electrode plate was placed into a chamber of an atomic layer deposition system, vacuumizing by using a mechanical pump to reduce the air pressure of the chamber to 0.01 Torr, then introducing a small amount of N₂ (100 sccm) was introduced to keep the fluidity of inert gas inside the cavity;
A2. a precursor trimethylaluminum was pulsed into a reaction chamber at 150° C. The valve opening and closing time: 0.5 s, the ALD reaction chamber pressure reached 2 Torr, the time of pressure maintaining for precursor was 1 s, for 1 time;
A3. 2000 sccm of N₂ was introduced and purged for 15 s;
A4. the reactant ozone (O₃) was introduced into the reaction chamber, wherein the pressure of the ALD reaction chamber reached 5 Torr, time of maintaining: 15 s, for 2 times;
A5. 2000 sccm of N₂ was introduced and purged for 30 s;
A6. the steps A2-A5 were cycled for 10 times to obtain the electrode protective layer with a thickness of 3.2 nm.

By adjusting the cycle number of step A6 in an equal proportion, this comparative example also prepared and obtained electrode protective layers with thicknesses of 1 nm, 5 nm and 10 nm, respectively.

### Test Example

This test example tests the performance of the negative electrode plates. The specific test method is as follows.

(1) Assembling of a graphite electrode plate-lithium plate half-cell. A wave elastic sheet of the button-cell shell made of 316 stainless steel (Canrd, 15.4 mm×1.0 mm), a gasket of the button-cell shell made of 316 stainless steel (Canrd, 15.5 mm×0.5 mm), a metal lithium plate, a separator (Celgard, a thickness of 25 μm, made of polypropylene) and a graphite negative electrode (Canrd SM0201) that was or was not processed by the passivation layer were sequentially placed in the button-cell shell made of 316 stainless steel (Canrd). Wherein several drops of electrolyte (graphite button battery electrolyte, Canrd KLD-1230C) were dripped into the surface of the lithium plate and separator before and after the separator was Installed. Finally, the installed battery above was compacted by using a hydraulic tablet press to complete the assembly of the half-cell buckling.

(2) Cycle test of the half-cell. The half-cell was installed on a LANHE cell test system and placed at a test environment of 25(±1° C.) for testing. In the first 2 cycles, the battery was activated by charge and discharge at a constant current of 0.1 C. In subsequent cycles, charge and discharge was performed at a constant current of 0.2 C, and the test voltage was 0-2.0V.

(3) Rate performance test of the half cell. The test voltage was 0-2.0V, after activating and cycling for 2 cycles by the same method as the cycle test, the discharge capacities of the battery at 0.1 C/0.1 C, 0.2 C/0.2 C, 0.5 C/0.5 C, 1 C/1 C and 2 C/2 C were sequentially tested, each rate test was performed for 6 cycles, and after the above rate tests were finished, the recovery condition of the battery performance was observed by cycling for 6 cycles at 0.1 C/0.1 C.

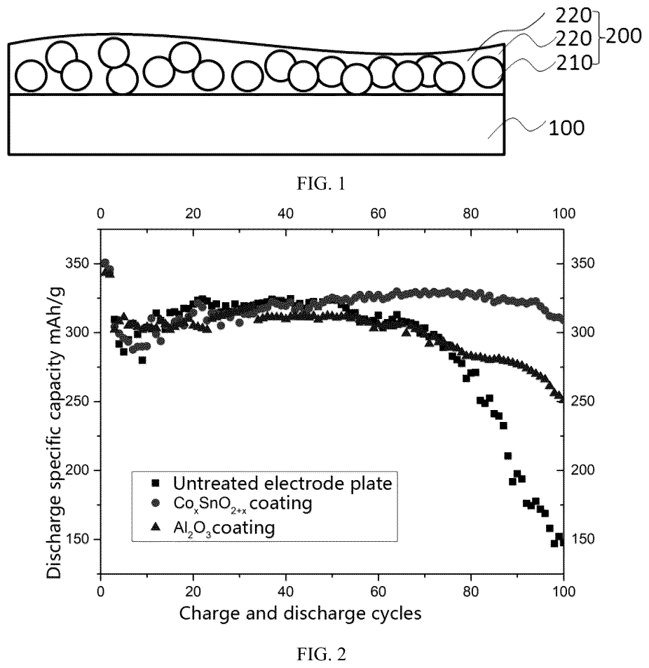

The discharge specific capacity graph of the electrochemical performance of the commercial graphite negative electrode plate used in Example 3 and the negative electrode plates prepared in Example 3 and Comparative Example 1 is shown in FIG. 2.

It can be seen from FIG. 2 that the specific capacity of the negative electrode plate formed by the CoₓSnO₂₊ₓ electrode protective layer (with a thickness of 3.2 nm) prepared by the atomic layer deposition method in Example 3 has a slow decrease trend and can be maintained above 300 mAh/g; compared with the untreated commercial graphite negative electrode plate, the specific capacity of the negative electrode plate is greatly decreased after 60 cycles, and is decreased to below 150 mAh/g after 100 charge and discharge cycles. Therefore, It can be seen that the cycle life of the negative electrode plate coated by the electrode protective layer is greatly prolonged. In addition, the commercial plate coated with Al₂O₃ (with a thickness of 3.2 nm) prepared by atomic layer deposition in the first 30 cycles shows similar cycle performance to the CoₓSnO₂₊ₓ coated plate; and with a subsequent slow decrease in capacity, the overall performance of the commercial plate is weaker than that of CoₓSnO₂₊ₓ coated plate but better than that of uncoated plate. The reason is that the thickness of Al₂O₃ coating is thinner and the ionic conductivity is poor.

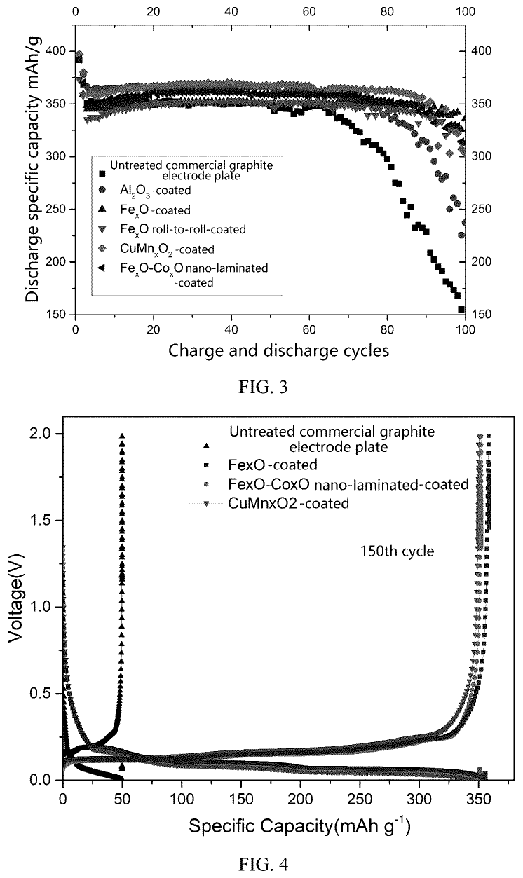

The cycle performances of the commercial graphite negative electrode plate used in Example 1, the negative electrode plate in Comparative Example 1 (coated with Al₂O₃), the negative electrode plate used Example 2 (deposited FeₓO by static atomic layer deposition), the negative electrode plate in Example 8 (deposited FeₓO by roll-to-roll deposition), the negative electrode plate in Example 4 (coated with CuMnₓO₂), and the negative electrode plate in Example 5 (coated with CoₓO/Fe_{y}O) are shown in FIG. 3 (the thicknesses of all the electrode protective layers are 5 nm), and the results in FIG. 3 show that the electrode protective layers with any of static atomic layer deposition, the dynamic atomic layer deposition and different materials can achieve similar secondary battery negative electrode protection effects, and are significantly better than the performances of the untreated commercial graphite negative electrode plate and the commercial graphite negative electrode plate that is treated with Al₂O₃.

The charge and discharge curves of the lithium batteries consisting of the commercial graphite negative electrode plate raw material of examples, and negative electrode plates in Example 2 and 4-5 at 150 cycles are shown in FIG. 4 (the thickness of the electrode protective layer is 5 nm).

FIG. 4 shows that comparing with the negative electrode plate without the electrode protective layer, the performance of the negative electrode plates of Example 2 (FeₓO), Example 4 (CuMnₓO₂) and Example 5 (CoₓO—Fe_{y}O) of the present disclosure is significantly better.

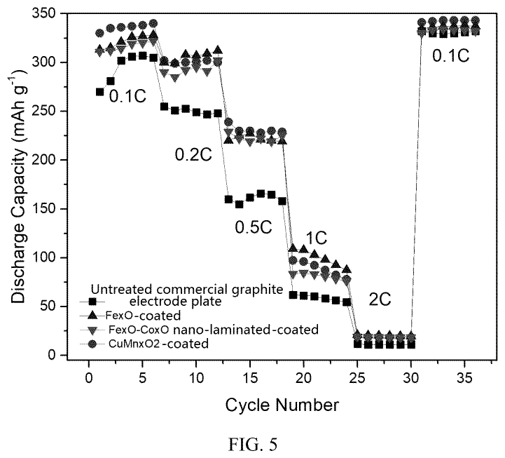

The rate performance diagram of the lithium batteries consisting of commercial graphite negative electrode plate raw material of examples, and the negative electrode plates in Examples 2 and 4-5 is shown in FIG. 5 (the thickness of the electrode protective layer is 5 nm).

FIG. 5 shows that whether or not the electrode protective layer is set has a little effect on the charge and discharge performance of the lithium-ion batteries at low rate (0.1 C). However, at rates of 0.2 C, 0.5 C and IC, the protective performance of the electrode protective layer is reflected, which significantly improving the rate performance of the resulting battery. 0.2 C-1 C is a common used rate for lithium-ion battery. Therefore, the electrode protective layer provided by the present disclosure has broad application prospects in various types of lithium-ion batteries. If the rate continues to be increased, the impedance brought by the electrode protective layer is larger, so it may have a certain impact on high rate.

This test example also compiled the electrochemical performance results of the negative electrode plates obtained in examples and comparative example, as well as the corresponding results of between above performance and the material and thickness of the electrode protective layer, as shown in Tables 1-3.

In Tables 1-3, the thickness of the electrode protective layer is calibrated according to the metal content in the electrode protective layer, specifically, the metal content in the electrode protective layer deposited on the negative electrode plate has a linear relationship with the thickness of the film deposited on the silicon dummy wafer (when the electrode protective layer is deposited, the silicon dummy wafer is deposited at the same time and under the same conditions), and the film thickness of the silicon dummy wafer can be accurately measured by ellipsometer, so as to calibrate the electrode plate content.

TABLE 1
Electrochemical performance of the negative electrode plate with
the single-layer binary oxide as the electrode protective layer

| | | | First-cycle | | | |
|---|---|---|---|---|---|---|
| | | | discharging | Capacity retention | | |
| | | Thick- | specific | rate % | | |
| | | ness | capacity | 50 | 100 | 150 |
| | Material | (nm) | (mAh/g) | cycles | cycles | cycles |
| | — | — | 373 | 97 | 63.5 | 44.7 |
| Exam- | CoₓO | 10 | 365 | 99 | 98.1 | 94.9 |
| ple 1 | CoₓO | 5 | 364 | 98 | 97.7 | 94.5 |
| | CoₓO | 1 | 366 | 99 | 98.6 | 95 |
| Exam- | In₂O₃ | 10 | 368 | 98.5 | 98.2 | 94.6 |
| ple 9 | In₂O₃ | 5 | 370 | 98.2 | 98 | 94.1 |
| | In₂O₃ | 1 | 371 | 99 | 98.5 | 92.1 |
| Exam- | FeₓO | 5 | 369 | 99.5 | 99.2 | 92.3 |
| ple 2 | | | | | | |
| Exam- | MnₓO | 5 | 370 | 98.6 | 98.3 | 92 |
| ple 10 | | | | | | |
| Exam- | NiO | 5 | 374 | 99 | 98.5 | 91.5 |
| ple 11 | | | | | | |
| Exam- | CuO | 5 | 372 | 98.6 | 98.2 | 94.8 |
| ple 12 | | | | | | |
| Exam- | ZnO | 5 | 374 | 98.7 | 98.3 | 95 |
| ple 13 | | | | | | |
| Exam- | Nb₂O₅ | 5 | 375 | 99 | 98.6 | 94.9 |
| ple 14 | | | | | | |
| Exam- | CoₓO | 5 | 373 | 98.8 | 98.5 | 94.6 |
| ple 15 | dynamic | | | | | |
| | device | | | | | |
| Exam- | In₂O₃ | 5 | 371 | 98.9 | 98.4 | 94.8 |
| ple 16 | dynamic | | | | | |
| | device | | | | | |

The results in Table 1 show that the cycle performance of the negative electrode plate deposited with the electrode protective layer is significantly improved, the capacity retention rate after 50 complete cycles is ≥98% (the ratio of the discharge capacity at the 50^{th} cycle to the discharge capacity at the first cycle, and so on), the capacity retention rate after 100 cycles is ≥97.7%, and the capacity retention rate after 150 cycles is ≥91.5%. Since this test example uses button battery for testing, the cycle performance can not be fully exerted. It can be predicted that when the negative electrode plate obtained by the present disclosure is used in full battery, the cycle performance of the obtained full battery will be further better than the cycle performance test results in Table 1.

By comparing the thickness of the electrode protective layer and the battery performance in Examples 1 and 9, it can be known that, in a thickness range of 1-10 nm, the electrode protective layer can significantly improve the performance of the obtained negative electrode plate, and the optimal thickness of the electrode protective layer is related to the material of the electrode protective layer, for example, when the electrode protective layer is made of CoₓO, a thinner (e.g., 1 nm) electrode protective layer can play a good role in protection; when the electrode protective layer is made of In₂O₃, a thicker electrode protective layer (e.g., 10 nm) has better performance.

TABLE 2
Electrochemical performance of the negative electrode
plate with the single-layer ternary oxide or laminated
structure as the electrode protective layer

| | | | First- | | | |
|---|---|---|---|---|---|---|
| | | | cycle dis- | | | |
| | | | charging | Capacity retention | | |
| | | Thick- | specific | rate % | | |
| | | ness | capacity | 50 | 100 | 150 |
| | Material | (nm) | (mAh/g) | cycles | cycles | cycles |
| | — | — | 373 | 97 | 63.5 | 44.7 |
| Exam- | CoₓSnO₂₊ₓ | 10 | 367 | 99 | 98.8 | 92.5 |
| ple 3 | CoₓSnO₂₊ₓ | 5 | 369 | 98.8 | 99.1 | 94.6 |
| | CoₓSnO₂₊ₓ | 1 | 369 | 99 | 98.5 | 90.6 |
| Exam- | CuMnₓO₂ | 10 | 372 | 98.6 | 98.3 | 93.5 |
| ple 4 | CuMnₓO2 | 5 | 371 | 98.7 | 98.4 | 94.2 |
| | CuMnₓO2 | 1 | 372 | 98.8 | 98.6 | 91.7 |
| Exam- | Li₄Ti₅O₁₂ | 5 | 368 | 98.6 | 98.3 | 94.3 |
| ple 17 | | | | | | |
| Exam- | TiNb₂O₇ | 5 | 369 | 99.2 | 98.4 | 94.2 |
| ple 18 | | | | | | |
| Exam- | CoSb₂O₆ | 5 | 366 | 99 | 98.4 | 92.1 |
| ple 19 | | | | | | |
| Exam- | CoₓO/Fe_{y}O | 5 | 371 | 98.8 | 98.5 | 90.1 |
| ple 5 | | | | | | |
| Exam- | CoₓO/In₂O₃ | 5 | 368 | 98.7 | 98.6 | 93.8 |
| ple 20 | | | | | | |
| Exam- | In₂O₃/ZnO | 5 | 366 | 99.1 | 98.3 | 94.1 |
| ple 21 | | | | | | |

The results in Table 2 show that when the electrode protective layer is a single-layered ternary oxide or has a laminated structure, they are equivalent to the effect of a single-layered binary oxide.

However, it can be seen from comparing the results corresponding to electrode protective layers with different thicknesses in Example 3 and Example 4 that when the electrode protective layer is a ternary oxide, the thickness of the electrode protective layer has a more significant influence on the electrochemical performance of the negative electrode plate. Specifically, the thickness of 5 nm is preferable to that of 10 nm and 1 nm.

TABLE 3
Electrochemical performance results of negative electrode
plates obtained in some examples and comparative example

| | | | | First-cycle | | | |
|---|---|---|---|---|---|---|---|
| | | | | discharging | Capacity retention | | |
| | | | | specific | rate % | | |
| | | | Thickness | capacity | 50 | 100 | 150 |
| | Material | Method | (nm) | (mAh/g) | cycles | cycles | cycles |
| | — | — | — | 373 | 97 | 63.5 | 44.7 |
| Example 7 | Co₂SnO₄ | Magnetron | 5 | 371 | 98.2 | 94.5 | 93.8 |
| | | sputtering | | | | | |
| Example 22 | CoₓSnO₂₊ₓ | CVD | 5 | 372 | 98.6 | 90.1 | 88.9 |
| Example 3 | CoₓSnO₂₊ₓ | ALD | 5 | 369 | 98.8 | 99.1 | 94.6 |
| Example 23 | CuO | Magnetron | 5 | 366 | 98.2 | 95.3 | 92.7 |
| | | sputtering | | | | | |
| Example 6 | CuO | CVD | 5 | 368 | 98.6 | 92.1 | 90.5 |
| Example 12 | CuO | ALD | 5 | 372 | 98.6 | 98.2 | 94.8 |

In Tables 1 to 3, the material and thickness refer to the material and thickness of the electrode protective layer; the method is the setting method for the electrode protective layer; “-” indicates absence or no testing.

The results in Table 3 show that the electrode protection layers with excellent protective performance can be obtained using different preparation methods. Compared among magnetron sputtering, CVD and ALD, due to the denser and more uniform protective layer formed by ALD, its protection performance is superior.

The battery formed by assembling the electrode protective layers of negative electrode plate formed by using other materials of the present disclosure has good ion transmission performance, and the cycle performance of the lithium-ion battery is also improved to different degrees.

The above provides a detailed explanation of the examples of the present disclosure in conjunction with specific embodiments. However, the present disclosure is not limited to the aforementioned embodiments. Within the scope of knowledge possessed by ordinary skilled in the art, various changes can be made without departing from the aim of the present disclosure. In addition, the embodiments of the present disclosure and features in those embodiments can be combined with each other without conflict.

1. An electrode protective layer, comprising a metal oxide, and having a 1 to multi-layer laminated structure, and the metal oxide has ionic conductivity;
wherein the metal oxide comprises at least one of a binary oxide and a ternary oxide;
wherein the binary oxide has a general formula of AOₘ;
in the AOₘ, A is independently selected from one of the group consisting of V, Mo, Nb, Sb, Ge, Zn, Cd, In, Co, Fe, Mn, Ni, Cu and Cr; and 1≤m≤3;
wherein the ternary oxide is at least one of titanate, niobate, stannate, antimonate and other transition-metal ternary oxides satisfying the general formula of XY₂O₄;
wherein the titanate is selected from at least one of the group consisting of Li₄Ti₅O₁₂ and MgTi₂O₅;
wherein the niobate is TiNb₂O₇;
wherein the stannate is selected from at least one of the group consisting of Mg₂SnO₄, MgSnO₃, Mn₂SnO₄, Co₂SnO₄, CoSnO₃, Zn₂SnO₄, CaSnO₃, SrSnO₃ and Li₂SnO₃;
wherein the antimonate is selected from at least one of the group consisting of CoSb₂O₆, NiSb₂O₆ and CuSb₂O₆.

2-3. (canceled)

4. The electrode protective layer according to claim 1, wherein the AOₘ is at least one of a stoichiometric oxide and a non-stoichiometric oxide.

5. The electrode protective layer according to claim 2, wherein the stoichiometric oxide is selected from at least one of the group consisting of VO, VO₂, V₂O₅, VₙO₂ₙ₋₁, MoO₃, Nb₂O₅, Sb₂O₃, GeO₂, ZnO, CdO, In₂O₃, CoO, Co₃O₄, FeO, Fe₂O₃, Fe₃O₄, MnO, Mn₂O₃, Mn₃O₄, NiO, CuO and Cr₂O₃;
in the VₙO₂ₙ₋₁, n is a positive integer.

6. (canceled)

7. The electrode protective layer according to claim 6, wherein the X and Y in the XY₂O₄ are independently selected from one of the group consisting of Mn, Fe, Co, Ni and Cu; and
the condition is that the X and the Y are different.

8-11. (canceled)

12. The electrode protective layer according to claim 1, wherein the electrode protective layer has a thickness of ≥0.1 nm.

13. A preparation method for the electrode protective layer according to claim 1, wherein the preparation method is an atomic layer deposition method, a chemical vapor deposition method, a physical vapor deposition method, or a combination thereof.

14. The preparation method according to claim 13, wherein the atomic layer deposition method comprises the following steps:
E1. placing a negative electrode plate of a secondary battery in a chamber of an atomic layer deposition system, vacuumizing, and sequentially or simultaneously introducing isolation gas, metal precursor and oxygen-containing reactant into the chamber for atomic layer deposition; and
E2. starting a moving mechanism to enable the plate to move and pass through the deposition area of the chamber for 1 to multiple times, so as to obtain the electrode protective layer.

15. The preparation method according to claim 14, wherein the metal precursor in step E1 has a flow rate of 0.1-500 SLM.

16. The preparation method according to claim 14, wherein the oxygen-containing reactant in step E1 has a flow rate of 0.1-500 SLM.

17. The preparation method according to claim 14, wherein the speed of motion in step E2 is at 0.01-300 m/min.

18. The preparation method according to claim 13, wherein the atomic layer deposition method comprises the following steps:
A1. adsorbing the metal precursor on the surface of the negative electrode plate of the secondary battery in the chamber for atomic layer deposition;
A2. introducing the oxygen-containing reactant into the chamber in step A1 to make the oxygen-containing reactant react with the metal precursor; and
A3. repeating the steps A1 to A2, and performing cyclic deposition to form the electrode protective layer that has 1 to multi-layer laminated structure, and it is made of the metal oxide; and the metal oxide is binary oxide.

19. The preparation method according to claim 13, wherein the atomic layer deposition method comprises the following steps:
B1. adsorbing a first metal precursor on the surface of the negative electrode plate of the secondary battery in the chamber for atomic layer deposition;
B2. introducing the oxygen-containing reactant into the chamber in step B1 to make the oxygen-containing reactant react with the first metal precursor;
B3. introducing a second metal precursor into the chamber in step B2 to make the second metal precursor adsorb on the surface of the product obtained in step B2;
B4. introducing the oxygen-containing reactant into the chamber in step B3 to make the oxygen-containing reactant react with the second metal precursor; and
B5. repeating the steps B1 to B4, and performing cyclic deposition to form the electrode protective layer that has 1 to multi-layer laminated structure, and it is made of the metal oxide, and the metal oxide is a ternary oxide.

20. The preparation method according to claim 13, wherein the atomic layer deposition method comprises the following steps:
C1. adsorbing a first metal precursor on the surface of the negative electrode plate of the secondary battery in the chamber for atomic layer deposition;
C2. introducing the oxygen-containing reactant into the chamber in step B1 to make the oxygen-containing reactant react with the first metal precursor;
C3. repeating the steps C1 to C2 to obtain a first metal oxide layer;
C4. introducing a second metal precursor into the chamber in step C3 to make the second metal precursor adsorb on the surface of the first metal oxide layer;
C5. introducing the oxygen-containing reactant into the chamber in step C4 to make the oxygen-containing reactant react with the second metal precursor;
C6. repeating the steps C4 to C5, and performing cyclic deposition to form a second metal oxide layer; and
C7. cycling the steps C1 to C6, and performing cyclic deposition to form the electrode protective layer that has a multi-layer laminated structure, and it is made of the metal oxide.

21. The preparation method according to claim 13, wherein the chemical vapor deposition method is one of an atmospheric pressure chemical vapor deposition method, a low pressure chemical vapor deposition method, and a plasma enhanced chemical vapor deposition method, or a combination thereof.

22. The preparation method according to claim 21, wherein the low pressure chemical vapor deposition method comprises the following steps:
F1. placing the negative electrode plate of the secondary battery in a chamber of a low-pressure hot-wall chemical vapor deposition system, vacuumizing and cleaning; and
F2. introducing the metal precursor and the oxygen-containing reactant into the chamber in step F1, and reacting to obtain the electrode protective layer.

23. The preparation method according to claim 13, wherein the physical vapor deposition method is one of evaporation, magnetron sputtering, and pulse laser deposition method.

24. The preparation method according to claim 23, wherein the magnetron sputtering method comprises the following steps:
G1. placing the negative electrode plate of the secondary battery into a magnetron sputtering system, and vaccumizing;
G2. sputtering a transition layer on the surface of the negative electrode plate of the secondary battery in a protective gas atmosphere; and
G3. sputtering the electrode protective layer on the surface of the transition layer.

25. A negative electrode, comprising the electrode protective layer according to claim 1, an active material, a binder, a conductive agent, and a current collector.

26. A negative electrode according to claim 25, wherein the active material comprises at least one of graphite, graphene, carbon nanotubes, vapor grown carbon fibers, silicon carbon, silicon, lithium metal, sodium metal, and transition metal oxides.

27. A secondary battery, comprising the negative electrode according to claim 25.

28. (canceled)
